(19) United States
(12) Patent Application Publication
(10) Pub. No.: US 2024/0424937 A1
(43) Pub. Date: Dec. 26, 2024

(54) METHOD AND DEVICE FOR THE VOLTAGE-LEVEL DETERMINING OF A CHARGING CONTROL-SYSTEM SIGNAL

(71) Applicant: Lisa Dräxlmaier GmbH, Vilsbiburg (DE)

(72) Inventor: Stephan SCHAFFERHANS, München (DE)

(73) Assignee: Lisa Dräxlmaier GmbH, Vilsbiburg (DE)

(21) Appl. No.: 18/742,063

(22) Filed: Jun. 13, 2024

(30) Foreign Application Priority Data
Jun. 21, 2023 (DE) 10 2023 116 188.1

(51) Int. Cl. B60L 53/62

(52) U.S. Cl. CPC B60L 53/62

(57) ABSTRACT

A method for the voltage-level determining of a charging control-system signal for charging systems of electric vehicles, in which the charging control-system signal is a pulse-width modulated, PWM, signal with adjustable pulse width and the method includes recording measurement values of the charging control-system signal in a time range prescribed by a measurement window. The method includes recognizing a falling slope of the charging control-system signal and of a corresponding time point of the falling slope based on the charging control-system signal and a prescribed threshold value; and upon recognizing the falling slope of the charging control-system signal, determining a voltage level of the charging control-system signal based on at least one first part of the measurement values of the charging control-system signal recorded in the measurement window, which measurement values have been recorded before the time point of the falling slope of the charging control-system.

### CROSS-REFERENCE TO RELATED APPLICATIONS

This application claims priority to and the benefit of DE 10 2023 116 188.1, filed on Jun. 21, 2023. The disclosure of the above-referenced application is incorporated herein by reference.

### FIELD

The present disclosure relates to a method and a device for the voltage-level determining of a charging control-system signal, in particular for charging systems of electric vehicles.

### BACKGROUND

The statements in this section merely provide background information related to the present disclosure and may not constitute prior art.

The pulse-width modulated (PWM) charging control-system signal for charging systems according to Type 1/CCS 1, Type 2/CCS 2 as well as for Megawatt Charging (MCS) must be evaluated for the charging process. Inter alia the height of the positive voltage signal level is to be determined. However, due to parasitic impedances, that is, capacitances and inductances in the signal path, as well as external interferences, this signal is often very noisy and may therefore not be measured with certainty.

Known solutions consist, for example, in stronger filtering of the PWM signal, a continuous sampling with subsequent averaging by software, as well as the detecting of a plurality of measurement values after a rising slope has been detected. However, these use an increased computing time from the processor in order to achieve a satisfactory measurement accuracy. In addition, the storage that may be needed with continuous sampling is not to be ignored.

### SUMMARY

This section provides a general summary of the disclosure and is not a comprehensive disclosure of its full scope or all of its features.

The present disclosure provides an improved voltage-level determining of the charging control-system signal, which makes possible an improved measuring of the voltage level with reduction of the interference of parasitic impedances. The present disclosure also provides an improved voltage measuring of a signal for the charging control system.

The present disclosure provides measuring of the voltage level with reduction of the interference of parasitic impedances.

The present disclosure provides measuring the voltage deliberately shortly before the falling slope instead of in the initial range of the high level, i.e., after the rising slope. This is made possible by a continuous sampling of the voltage signal and the signaling of the voltage evaluation by the falling slope of the PWM signal.

The present disclosure provides a precise voltage measurement by a continuous, rapid sampling of the PWM signal for the charging control system with the efficiency and storage-improved evaluation by a limited number of measurements at a certain trigger time point. Due to the placing of the measurement window at the end of the voltage plateau, the maximum swung-in state of the PWM signal is used, and thus a greatest-possible independence from the transient response of the signal is made possible.

According to a first aspect, the present disclosure provides a method for the voltage-level determining of a charging control-system signal for charging systems of electric vehicles, in which the charging control-system signal is a pulse-width modulated, PWM, signal with adjustable pulse width, in which the method comprises the following: Recording of measurement values of the charging control-system signal in a time span prescribed by a measurement window; recognizing of a falling slope of the charging control-system signal and a corresponding point in time of the falling slope based on the charging control-system signal and a prescribed threshold value; and, upon recognizing of the falling slope of the charging control-system signal, determining a voltage level of the charging control-system signal based on at least one first part of the measurement value, detected in the measurement window, of the charging control-system signal, which has been detected before the point in time of the of falling slope of the charging control-system signal.

Such a method leads to an improved voltage-level determining of the charging control-system signal, with which an improved measuring of the voltage level with reduction of the interference of parasitic impedances.

Due to the placing of the measurement window before the falling slope of the PWM signal, the maximum swung-in state of the PWM signal is used and thus an increased independence from the transient response of the signal is made possible. The measurement window is adapted to the swung-in state of the PWM signal, and a storage of the measurement values may thus occur in a resource-saving manner when only measurement values in the swung-in state are considered for the determining of the voltage level.

According to one example of the method, the recognizing of the falling slope of the charging control-system signal is affected based on a comparison of the charging control-system signal, or of a signal derived from the charging control-system signal, with the prescribed threshold value. The technical advantage of such a method lies in that the falling slope may be easily recognized in a manner depending on a threshold-value comparison. For example, for this purpose a simpler comparator may be used to which the prescribed threshold value is supplied.

According to one example of the method, the measurement window is set such that a plurality of measurement values are recordable within a part of the pulse width of the PWM signal.

The method provides that by using the plurality of measurement values, a more precise determining of the voltage level is possible than when only a single measurement value or a pair of small measurement values is used for this purpose. A determining via these multiple measurement values is therefore more precise than with only one or when a plurality of small measurement values are evaluated for this purpose.

According to one example of the method, the measurement window is set such that a plurality of measurement values are recordable within a part of a minimally occurring pulse width of the PWM signal according to the standard IEC 61851-1.

The technical advantage of such a method lies in that all currents of the charging current that are signaled via the pulse width of the PWM signal may be recognized with certainty.

According to one example of the method the voltage level is determined without a second part of the measurement value recorded in the measurement window, which has been recorded directly before the point in time of the falling slope.

The technical advantage of such a method lies in that measurement values that have already been recorded in the point in time of the falling slope are not added into the determination of the voltage level, since these would otherwise distort the determining of the voltage level. A very high precision of the voltage-level determining may thus be guaranteed. The time point of the falling slope is based on a recorded time point that in particular was recorded by a comparator by a threshold value comparison. The actual physical time point of the start of the falling of the charging control-system signal may deviate from this.

For the threshold value comparison a threshold value may be used that has a sufficient spacing from the actual positive voltage level of the charging control-system signal for a fault-tolerant recording. From this a delay may arise, that is, the recorded time point of the falling slope may occur later than the actual falling of the voltage level of the charging control-system signal. Due to the omitting of the second part of the measurement values recorded in the measurement window, measurement values, which have been saved by this delay, belonging to the positive voltage level cannot remain unconsidered during the calculating of the value of the voltage level of the charging control-system signal.

A determining of the length of the second part may be based on a simulation or on experience values. The length of the second part may comprise a dynamically adapted number of store measurement values, or a predetermined fixed number of stored measurement values; for example, the newest measurement value before the time point of the falling slope is discarded, i.e., these discarded measurement values remain unconsidered during the determining of the voltage level of the charging control-system signal.

A dynamic test phase, in particular during start-up of the charging system, is likewise conceivable, in which different lengths of the second part are successively tested, in which the length of the second part after the test phase is set to the value that has produced the highest voltage level in the test phase and/or has the lowest variance of the voltage level.

According to one example of the method the determining of the voltage level is affected based on an averaging at least of the first part of the measurement values recorded in the measurement window.

The technical advantage of such a method lies in that only the measurement values shortly before the occurring of the falling slope, which have been recorded in the swung-in state of the PWM signal, are used for the averaging. Thus, no measured-value outliers that would distort the result are used for the averaging. The measurement accuracy of the voltage level determination is thus very high.

According to one example of the method, the method comprises a filtering of the charging control-system signal before the recording of the measurement values, wherein the filtering is effected with an analog filter that is configured to suppress signal superpositions in the charging control-system signal by an interference signal which, for example, originates from a power line signal. The analog filter may be, for example, a low-pass filter.

The technical advantage of such a method lies in that high-frequency oscillations due to an influencing of the charging control-system signal by a power line communication are previously filtered out, and thus the determining of the voltage level cannot be distorted.

According to one example of the method, the method comprises a sampling of the filtered charging control-system signal with an analog-digital converter for the obtaining of the measurement values of the charging control-system signal; and a storing of the sampled measurement values in a buffer storage, in which the size of the buffer storage corresponds to the time range prescribed by the measurement window.

The technical advantage of such a method lies in that such a buffer storage is efficiently adapted to the measurement window, and thus the recorded measurement values may be stored in a very resource-efficient manner. The buffer storage may respectively overwrite previously recorded measurement values by new measurement values, so that at the point in time of the falling slope only the measurement values are present in the storage that have been recorded in the swung-in state of the PWM signal. The time point at which the falling slope sets in and the time point at which the falling slope is detected may as a rule differ from each other, with the result that measurement values are already found in the buffer storage that have been recorded in the falling slope. However, these few measurement values may be efficiently detected and excluded from the determining of the voltage level.

According to one example of the method, the recognizing of the falling slope occurs based on a comparison of the filtered charging control-system signal with the prescribed threshold value; in which the prescribed threshold value corresponds to a signal level between a positive voltage level and a negative voltage level of the charging control-system signal.

The technical advantage of such a method lies in that the threshold value may be efficiently set with knowledge of the positive voltage level and of the negative voltage level; it may be set, for example, in the middle between positive and negative voltage level.

According to a second aspect, the present disclosure provides a device for the voltage-level determining of a charging control-system signal for charging systems of electric vehicles, in which the charging control-system signal is a pulse-width modulated, PWM, signal with adjustable pulse width, in which the device comprises the following: an analog-digital converter for the recording of measurement values of the charging control-system signal; a buffer storage for the storing of the recorded measurement values over a prescribed time range; a comparator for the recognizing of a falling slope of the charging control-system signal based on the charging control-system signal and a prescribed threshold value; and a processor that is configured to determine, upon the detecting of the falling slope of the charging control-system signal, a voltage level of the charging control-system signal based on at least a first part of the measurement values stored in the buffer storage, which measurement values were recorded before the falling slope of the charging control-system signal.

The technical advantage of such a device lies in that an improved voltage-level determining of the charging control-system signal is made possible, in which a precise measuring of the voltage level may be realized with reduction of the interference of parasitic impedances.

As already described above for the corresponding method according to the first aspect, due to the placing of the measurement window before the falling slope of the PWM signal, the maximum swung-in state of the PWM signal is used, and thus a greatest possible independence from the transient response of the signal is made possible. The measurement window is adapted to the swung-in state of the PWM signal, and a storing of the measurement values may thus occur in a resource-saving manner, since only measurement values in the swung-in state are considered for the determining of the voltage level.

According to a third aspect, the present disclosure provides a computer program product, comprising commands that, during the executing of the program by a computer, cause the computer to carry out the method according to the first aspect.

According to a fourth aspect, the present disclosure provides a computer-readable storage medium, comprising commands that, during the executing of the program by a computer, cause the computer to carry out the method according to the first aspect.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1A shows an example illustration of a Control Pilot (CP) signal with parasitic signal components, which represents a charging control-system signal for a charging system according to the present disclosure;

FIG. 1B shows an example illustration of the CP signal from FIG. 1A after filtering with an analog filter according to the present disclosure;

FIG. 2A shows a schematic illustration of a method for the voltage-level determining of a charging control-system signal according to the present disclosure;

FIG. 2B shows an example illustration of the CP signal from FIGS. 1A and 1B for use in the method from FIG. 2A;

FIG. 3 shows a schematic illustration of a method for the voltage-level determining of a charging control-system signal according to an example of the present disclosure;

FIG. 4 shows a schematic illustration of a buffer storage for use in the method depicted in FIG. 3; and

FIG. 5 shows a schematic illustration of a device for the voltage-level determining of a charging control-system signal.

Identical or functionally identical elements are provided throughout with the same reference numbers.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the following detailed description, reference is made to the accompanying drawings that form a part thereof, and in which specific examples are shown as illustration, in which the present disclosure may be explained. It is understood that other examples may also be used, and structural or logical changes may also be undertaken, without deviating from the concept of the present disclosure. The following detailed description is therefore not to be understood in a limiting sense. Furthermore, it is understood that the features of the different examples described herein may be combined with one another if not specifically indicated otherwise.

The aspects and examples are described with reference to the drawings, in which identical reference numbers generally refer to identical elements. In the following description, for the purpose of explanation numerous specific details are presented to convey a detailed understanding of one or more aspects of the present disclosure. Known structures and elements are depicted in schematic form to facilitate the describing of one or more aspects or examples. It is understood that other examples may be used, and structural or logical changes may be undertaken, without deviating from the concept of the present disclosure.

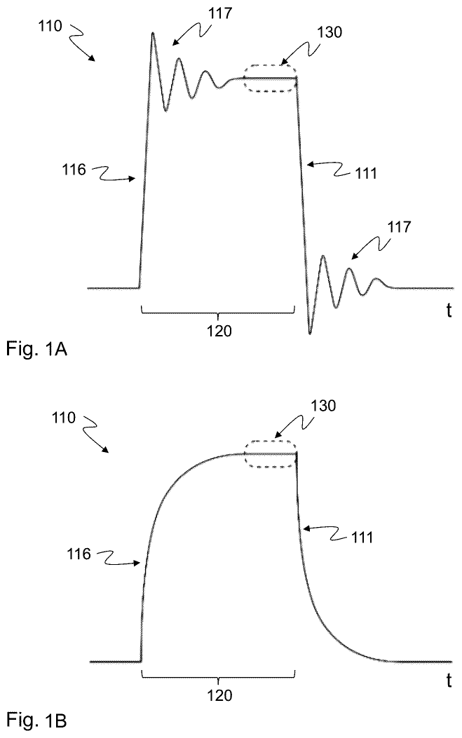

FIG. 1A shows an example representation of a Control Pilot (CP) signal 110 with parasitic signal components, which represents a charging control-system signal 110 for a charging system.

The Control Pilot signal 110 or charging control-system signal 110 conveys, for example, the available AC charging current, i.e., the current, which, for example, an AC wall box may provide.

The request for digital communication is initially coded by the Duty Cycle (i.e., the pulse width 120) of the PWM signal 110, and is desired for all DC charging processes with Type 1, Type 2, and MCS charging systems. For this purpose a PWM signal 110 with +12V/−12V and a frequency of 1 kHz is generated. For the evaluating of the signal, a transfer of the signal shape is desired, which, however, is hampered by parasitic effects in the signal path, as may be seen in FIG. 1A.

Parasitic impedances, i.e., capacitances or also inductances, may not be completely avoided in any electrical signal path; however, in charging systems with long charging cables these play a special role. The greater cable lengths provide that, for example, superimposed sine components 117 arise on the original rectangular PWM signal 110, as shown in FIG. 1A. These are strongly pronounced when only one new voltage level is impressed, that is, after a rising slope 116 or falling slope 111 of the original signal.

These sine components 117 appear as damped oscillation, which overlay the rectangular signal. A measurement of the impressed voltage level is only very imprecise during this first time range after a rising slope 116 or falling slopes 111 of a voltage when the oscillations, or sine components 117, are not specifically filtered out.

FIG. 1B shows an example representation of the CP signal 110 from FIG. 1A after filtering with an analog filter.

A too-strong filtering of the signal 110, or also a high parasitic capacitance component in contrast provides a rising slope 116 that is cut-off at the start of the voltage plateau, as depicted in FIG. 1B. Also, here the measurement of the original signal level is impaired.

In order to obtain a precise-as-possible measurement result, the swung-in state of the signal must be awaited. The measurement window 130 (dashed region in the graphics) thus lies shortly before the renewed signal change, that is, shortly before the falling slope 111 of the PWM signal 110.

Common solutions use, for example, the rising slopes 116 of the signal to start an ADC measurement with one or more measurement points. However, since without knowledge of the duty cycle, or pulse width 120, it is not clear when exactly the falling slope 111 will arrive, it is difficult to meet this time point (based on the rising slope 116).

There are thus two approaches: a fixed dead time between rising slope 116 and start of measuring, or a continuous measuring with subsequent determining of the measurement time point for the voltage evaluation.

In the first case, there may be difficulty in maintaining sufficient distance from the interfering signals in the direct connection to the rising slope 116, and simultaneously not erroneously measuring out past the time point of the falling slope 111.

In the second case, the storage standards for the measurement points to be recorded is high. Since the signal shape only repeats after 1 ms, it is advisable to maintain for this period all measurement values in a buffer storage, and then by software to select and evaluate the appropriate measurement window 130.

For the quality of the measuring, the sampling rate is an important factor. The faster and more frequently the signal 110 is sampled, the smaller the influences of interferences or noisy signal components, since these may be filtered out by an averaging. However, a rapid sampling is accompanied by a high storage requirement, since many data points are to be recorded and buffered.

The storage requirement can be reduced by only maintaining a limited time window 130 in the buffer storage, and evaluating these measurement points at an appropriate point in time. The best possible time point is marked by the falling slope 111 of the PWM signal 110 to be measured.

In the following, a method 100 is described that uses such a limited time window 130 for the recording of the measurement values.

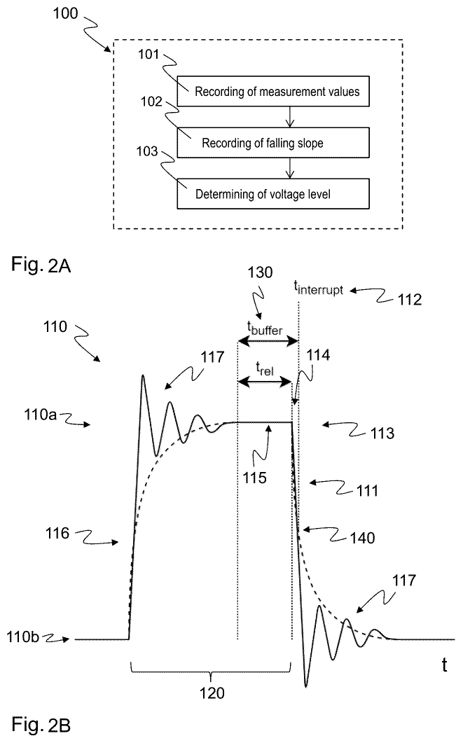

FIG. 2A shows a schematic representation of a method 100 for the voltage-level determining of a charging control-system signal, and FIG. 2B shows an example representation of the CP signals 110 from FIGS. 1A and 1B with characteristic parameters for use in the method 100 from FIG. 2A.

The charging control-system signal 110 is, for example, a pulse-width modulated signal, that is, PWM signal, with adjustable pulse width 120, that is used in charging systems of electric vehicles, for example, according to the standard IEC 61851-1 or other common standards.

The method 100 includes: recording 101 of measurement values of the charging control-system signal 110 in a time range prescribed by a measurement window 130; recognizing 102 of a falling slope 111 of the charging control-system signal 110 and of a corresponding time point 112 of the falling slope 111 based on the charging control-system signal 110 and a prescribed threshold value 140; and upon recognizing of the falling slope 111 of the charging control-system signal 110: determining 103 a voltage level 113 of the charging control-system signal 110 based on at least one first part 115 of the recorded measurement values of the charging control-system signal 110 in the measurement window 130, which measurement values have been recorded before the time point 112 of the falling slope 111 of the charging control-system signal 110.

The recognizing 102 of the falling slope 111 of the charging control-system signal 110 may be affected, for example, based on a comparison of the charging control-system signal 110, or of a signal derived from the charging control-system signal 110, for example, of an average time of the measurement values of the charging control-system signal 110, with the prescribed threshold value 140.

The measurement window 130 may be set such that a plurality of measurement values are recordable within a part of the pulse width 120 of the PWM signal 110.

For example, the measurement window 130 may be set such that a plurality of measurement values are recordable inside a part of a minimally occurring pulse width 120 of the PWM signal 110 according to the standard IEC 61851-1.

The voltage level 113 may be determined, for example, without a second part 114 of the measurement values recorded in the measurement window 130, which measurement values have been recorded directly before the time point 112 of the falling slope 111. As depicted in FIG. 2B, the second part 114 is the measurement values that have already been recorded with the setting-in of the falling slope 111, but the threshold value comparison with the threshold value 140 has not yet taken effect.

The determining 103 of the voltage level 113 may be affected, for example, based on an averaging of at least the first part 115 of the measurement values recorded in the measurement window 130. This first part 115 is the adjusted measurement values that do not include the second part 114, that have been recorded with the setting-in of the falling slope 111.

The method 100 may furthermore include a filtering of the charging control-system signal 110 before the recording 101 of the measurement values, in which the filtering is affected with an analog filter that is configured to suppress signal superpositions in the charging control-system signal 110, for example, caused by an interference signal, for example, a power line signal or another high-frequency signal. The analog filter may be, for example, a low-pass filter, which is set such that only the high frequencies of the PWM signal 110 are allowed through, but the high frequencies of the power line signal are no longer allowed through.

The method 100 may further include: sampling of the filtered charging control-system signal with an analog-digital converter for the obtaining of the measurement values of the charging control-system signal 110; and storing of the sampled measurement values in a buffer storage. Here a size of the buffer storage may correspond to the time range prescribed by the measurement window 130, as depicted in FIG. 2B.

The recognizing 102 of the falling slope 111 may occur based on a comparison of the filtered charging control-system signal 110 with the prescribed threshold value 140.

The prescribed threshold value 140 may correspond to, for example, a signal level between a positive voltage level 110a and a negative voltage level 110b of the charging control-system signal 110, as depicted in FIG. 2B.

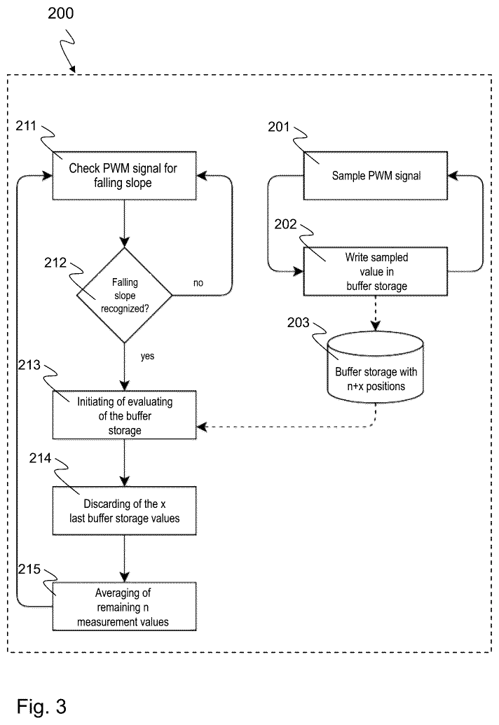

FIG. 3 shows a schematic representation of a method 200 for the voltage-level determining of a charging control-system signal 110 according to one example.

The method 200 has two paths, a first path with the blocks 201, 202, and 203, and a second path with the blocks 211, 212, 213, 214, and 215, in which the second path is influenced by the first path.

The first path starts with the sampling 201 of the PWM signal, which corresponds to the PWM signals 110 or charging control-system signals 110 described above for FIGS. 1A to 2B.

Then a writing 202 occurs of the sampled value in a buffer storage, and at the next sampling time point a further sampled value of the PWM signal is sampled 201 and again written 202 in the buffer storage.

After a certain number of times of repeating of the sampling 201 and writing 202, the buffer storage finally has a number of n+x points or sampled values of the PWM signal 110.

The second path starts with a checking 211 of the PWM signal for a falling slope 111. If in step 212 a falling slope 111 is recognized, then the initiating 213 occurs of the evaluating or evaluation of the buffer storage as it is in step 203. Otherwise, a renewed checking 211 occurs of the PWM signal 110 for a falling slope 111.

During the evaluating or evaluation of the buffer storage, in step 214 the x last buffer-storage values are discarded. That is, the length of the second part 114 of the buffer storage values corresponds to the number of the x discarded buffer storage values.

In the subsequent step 215, an averaging is affected of the remaining n measurement values. After the averaging 215, a voltage level of the PWM signal 110 is present.

Then a renewed checking 211 is affected of the PWM signal 110 for a falling slope 111.

The method 200 is one example of the method 100 described above for FIGS. 2A and 2B.

The recording 101 of measurement values of the charging control-system signal 110 in a time range prescribed by a measurement window 130 corresponds to the steps 201, 202, and 203, in which in step 203 these recorded measurement values are present in the buffer storage.

The recognizing 102 of a falling slope 111 of the charging control-system signal 110 and of a corresponding time point 112 of the falling slope 111 corresponds to the steps 211 and 212.

The determining 103 of a voltage level 113 of the charging control-system signal 110 corresponds to the steps 213, 214, and 215.

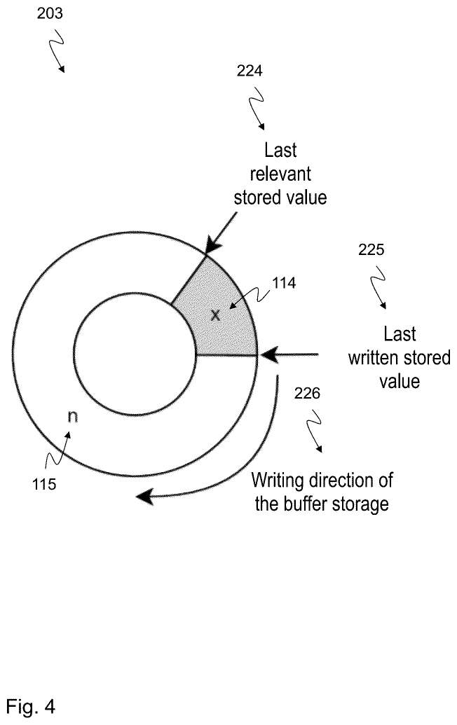

FIG. 4 shows a schematic representation of a buffer storage 203 for use in the method 200 depicted in FIG. 3.

The buffer storage 203 is used in accordance with the step 203 of the method 200 depicted in FIG. 2A. After each sampling 201 of the PWM signal 110 there is a measurement value or sampled value of the PWM signal 110, which measurement value or sampled value is written in the buffer storage 203. The writing direction 226 of the buffer storage 203 occurs, for example, clockwise, as depicted in FIG. 4. The next sampled value for the next sampling is written in the buffer storage 203 one position further in the clockwise direction.

In step 203 according to FIG. 2A, a number of n+x sampled values are written in the buffer storage 203 as stored values, in which of these n sampled values, or the first part 115, are relevant, namely those that have been written in the buffer storage before the setting-in of the falling slope 111, and in which x sampled values, corresponding to the second part 114, are not relevant and are to be discarded, namely those that have been written in the buffer storage during or after the setting-in of the falling slope 111. The last relevant stored value 224 corresponds to the last sampled value of the n sampled values, or the first part 115, while the last written stored value 225 corresponds to the last sampled value of the x sampled values in the second part 114.

The measurement window 130 described above for FIGS. 2A and 2B thus includes all n+x sampled values that fit in the buffer storage 203. The first part 115 of the measurement values, according to FIGS. 2A and 2B, recorded in the measurement window 130 includes the n relevant sampled values, or the first part 115, while the second part 114 of the measurement values, according to FIGS. 2A and 2B, recorded in the measurement window 130 includes the x sampled values to be discarded that have still been stored in the buffer storage 203, that is, the length of the second part 114 is x.

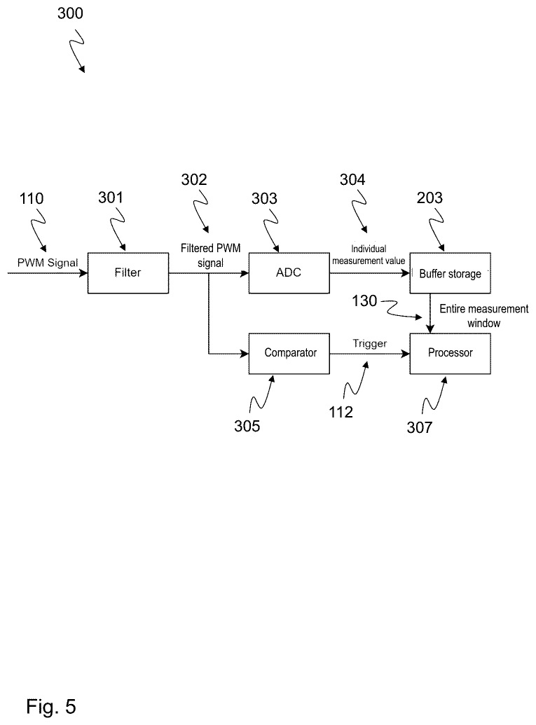

FIG. 5 shows a schematic representation of a device 300 for the voltage-level determining of a charging control-system signal 110.

The device 300 is analogous to the method 100 described above for the FIGS. 2A and 2B.

The device 300 serves for the voltage-level determining of a charging control-system signal 110 for charging systems of electric vehicles, wherein the charging control-system signal 110 is a pulse-width modulated, PWM, signal with adjustable pulse width.

The device 300 comprises an analog-digital converter 303 for the recording 101 of measurement values 304 of the charging control-system signal 110, for example, as described above for the FIGS. 2A and 2B.

The device 300 includes a buffer storage 203 for the storing of the recorded measurement values over a prescribed time range, for example, as described in more detail above for FIGS. 3 and 4.

The device 300 includes a comparator 305 for the recognizing 102 of a falling slope 111 of the charging control-system signal 110 based on the charging control-system signal 110 and a prescribed threshold value 140, for example, as described above for the FIGS. 2A, 2B, 3, and 4.

The device 300 includes a processor 307 that is configured to determine, upon recognizing the falling slope 111 of the charging control-system signal 110, a voltage level 113 of the charging control-system signal 110 based on at least one first part 115 of the measurement values 304 stored in the buffer storage 203, which measurement values 304 have been recorded before the falling slope 111 of the charging control-system signal 110, for example, as described above for the FIGS. 2A, 2B, 3, and 4.

Optionally the device 300 may include an analog filter 301 that is configured to filter the PWM signal 110 before it is supplied as filtered signal 302 to the AD converter 303 and to the comparator 305.

The analog filter 301 may be configured to filter the charging control-system signal 110 before the recording 101 of the measurement values. The analog filter 301 may be configured to suppress signal superpositions in the charging control-system signal 110 by an interference signal, for example, caused by a power line signal.

The analog-digital converter 303 may be configured to sample the filtered charging control-system signal 302 in order to obtain the measurement values of the charging control-system signal 110.

The buffer storage 203 may be configured to store the sampled measurement values. Here a size of the buffer storage 203 may correspond to the time range prescribed by the measurement window 130.

In the following, an example of the device 300 is described in more detail.

The present disclosure provides that a microcontroller carries out a continuous, high-frequency sampling of the PWM signal 110, in which the individual sampled values 304 are written directly in a buffer storage 203. The provided storage region with n+x positions is smaller here than would be desired for the recording of a complete period of the PWM signal 110 (approximately 1 ms). The time range covered by the buffer storage 203 is indicated, for example, with t_{buffer}.

If the end of the provided storage region is reached, the oldest measurement values are to be discarded and replaced by new sampled values (called First In First Out/FIFO storage or also ring storage). In order to determine when the optimal signal component is located in the buffer storage 203, an interrupt is generated in the microcontroller at time point tᵢₙₜₑᵣᵣᵤₚₜ 112 (see FIG. 2B) by the falling slope 111 of the PWM signal 110, and the contents of the buffer storage 203 are processed.

It may be advantageous here to discard a number x of the newest measurement values, or the second part 114 (as depicted in FIG. 4), since the start of the falling slope 111 has possibly also been measured and should not enter in with the evaluation. The relevant time component to be evaluated of the signal is indicated with tᵣₑₗ, and contains n measurement values (as depicted in FIG. 4). The n measurement values are averaged, and the positive voltage level 110a of the PWM signal 110 is calculated therefrom.

The signal flow may effectively be divided into two paths: an analog signal flow runs over the ADC 303 into the buffer storage 203; and a digital signal flow runs over a comparator 305 as trigger directly into the processor 307.

In order to write the ADC measurement values 304 directly into the buffer storage, a microcontroller with DMA functionality may be used. Thus, the processor load for the recording and storing of the individual measurement points 304 remains as low as possible.

The size of the measurement window 130 may be derived from the minimum duty cycle, or pulse width 120, to be recorded of the PWM signal 110. In accordance with the common standards (for example, IEC 61851-1), a minimum Duty Cycle of 3% with a maximum frequency of 1020 Hz should be able to be cleanly recorded. From this a positive pulse width of approximately 29 μs results. Taking into consideration the maximum allowable Setting Time or swing-in time (i.e., the duration up to 95% of the signal level should be achieved) of 3 μs, in an undisturbed system a minimum pulse width thus results of approximately 26 μs. If a further 10 μs are taken into account for the swing-in process of the signal disturbed by parasitic impedances, a minimum suitable measurement window results of 16 μs. With a sampling rate of 1 MHz, this corresponds to 16 measurement values inside the measurement window.

In order to preclude that the falling slope 111 of the signal 110 is also measured, for example the last two measurement values may be discarded, which corresponds to the maximum allowable Fall Time or falling time of 2 μs. Thus, the voltage level may be determined based on the remaining 14 measurement values by averaging.

The above-mentioned times are to be seen only as an example. By faster or slower sampling, as well as varying assumptions for the measurement window 130, other values may result for the measurement window size and the values to be recorded.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for determining a voltage-level of a charging control-system signal for charging systems of electric vehicles, the charging control-system signal is a pulse-width modulated (PWM) signal with adjustable pulse width, and the method comprises:
recording measurement values of the charging control-system signal in a time range prescribed by a measurement window;
recognizing a falling slope of the charging control-system signal and a corresponding time point of the falling slope based on the charging control-system signal and a prescribed threshold value; and
upon the recognizing the falling slope of the charging control-system signal, determining a voltage level of the charging control-system signal based on at least one first part of the measurement values of the charging control-system signal recorded in the measurement window, which measurement values have been recorded before the corresponding time point of the falling slope of the charging control-system signal.

2. The method according to claim 1, wherein the recognizing the falling slope of the charging control-system signal is based on a comparison of the charging control-system signal with the prescribed threshold value.

3. The method according to claim 1, wherein the recognizing the falling slope of the charging control-system signal is based on a comparison of a signal derived from the charging control-system signal with the prescribed threshold value.

4. The method according to claim 1, wherein the measurement window is set such that a plurality of measurement values are configured to be recorded inside a part of a pulse width of the PWM signal.

5. The method according to claim 1, wherein the measurement window is set such that a plurality of measurement values are configured to be recorded inside of a part of a minimally occurring pulse width of the PWM signal.

6. The method according to claim 1, wherein the voltage level is determined without a second part of the measurement values recorded in the measurement window, and the measurement values are recorded directly before the corresponding time point of the falling slope.

7. The method according to claim 1, wherein the determining the voltage level is based on an averaging of the at least one first part of the measurement values recorded in the measurement window.

8. The method according to claim 1, further comprising:
filtering the charging control-system signal before the recording of the measurement values, and the filtering occurs with an analog filter configured to suppress signal superpositions in the charging control-system signal caused by an interference signal.

9. The method of claim 8, wherein the interference signal is a power line signal.

10. The method according to claim 8, further comprising:
sampling the filtered charging control-system signal with an analog-digital converter to obtain the measurement values of the charging control-system signal; and
storing the sampled measurement values in a buffer storage, wherein a size of the buffer storage corresponds to a time range of the measurement window.

11. The method according to claim 8, wherein the recognizing the falling slope is based on a comparison of the filtered charging control-system signal with the prescribed threshold value, and the prescribed threshold value corresponds to a signal level between a positive signal level and a negative signal level of the charging control-system signal.

12. A device for determining a voltage-level of a charging control-system signal for a charging system of electric vehicles, the charging control-system signal is a pulse-width modulated (PWM) signal with adjustable pulse width, and the device comprises:
an analog-digital converter configured to record a plurality of measurement values of the charging control-system signal;
a buffer storage configured to store the plurality of measurement values over a prescribed time range;
a comparator configured to recognize a falling slope of the charging control-system signal based on the charging control-system signal and a prescribed threshold value; and
a processor configured to determine, upon recognizing the falling slope of the charging control-system signal, a voltage level of the charging control-system signal based on at least one first part of the plurality of measurement values stored in the buffer storage, and the plurality of measurement values are recorded before the falling slope of the charging control-system signal.
